(19) United States
(12) Patent Application Publication
(10) Pub. No.: US 2022/0005994 A1
(43) Pub. Date: Jan. 6, 2022

(54) DISPLAY DEVICE

(71) Applicant: Japan Display Inc., Tokyo (JP)

(72) Inventors: Tetsuo MORITA, Tokyo (JP); Hiroshi TABATAKE, Tokyo (JP); Yasuhiro OGAWA, Tokyo (JP)

(21) Appl. No.: 17/476,953

(22) Filed: Sep. 16, 2021

Related U.S. Application Data
(63) Continuation of application No. PCT/JP2020/003536, filed on Jan. 30, 2020.

(30) Foreign Application Priority Data
Mar. 20, 2019 (JP) 2019-052169

(51) Int. Cl. H01L 33/62; H01L 27/15; H01L 33/38

(52) U.S. Cl. CPC H01L 33/62; H01L 33/38; H01L 27/156

(57) ABSTRACT

According to one embodiment, a display device includes a substrate, a pixel electrode disposed on the substrate, a light emitting element mounted on the pixel electrode, a drive transistor configured to control a current supplied to the light emitting element through the pixel electrode, and a conductive layer formed between the pixel electrode and the drive transistor so as to at least partially overlap with the pixel electrode in a planar view. The conductive layer does not overlap with a region of the pixel electrode on which the light emitting element is mounted in a planar view.

### CROSS-REFERENCE TO RELATED APPLICATIONS

This application is a Continuation Application of PCT Application No. PCT/JP2020/003536, filed Jan. 30, 2020 and based upon and claiming the benefit of priority from Japanese Patent Application No. 2019-052169, filed Mar. 20, 2019, the entire contents of all of which are incorporated herein by reference.

### FIELD

Embodiments described herein relate generally to a display device.

### BACKGROUND

There is known an LED display using a light emitting diode (LED), which is a self-luminous element is known. Nowadays, a display device (in the following, referred to as a micro LED display) using a minute light emitting diode element called a micro LED is developed as a display device of higher definition.

Unlike a conventional liquid crystal display or organic EL display, this micro LED display is formed in which a large number of chip-shaped micro LEDs (in the following, referred to as an LED chip) are mounted in a display area, and thus it is easy to achieve both high definition and large size, and the micro LED display is attracting attention as a next-generation display.

The LED chip described above is mounted on an array substrate at the time of manufacturing the micro LED display, and at this time, the array substrate is easily damaged, which causes defects in the micro LED display.

### BRIEF DESCRIPTION OF THE DRAWINGS

FIG. 1 is a perspective view schematically illustrating the configuration of a display device according to an embodiment.

FIG. 2 is a plan view illustrating the circuit configuration of the display device.

FIG. 3 is a diagram illustrating an example of the circuit configuration of a pixel in the display device.

FIG. 4 is a diagram illustrating an example of the cross-sectional structure of a display device according to a comparative example of the present embodiment.

FIG. 5 is a diagram illustrating another example of the cross-sectional structure of the display device according to the comparative example of the present embodiment.

FIG. 6 is a diagram illustrating an example of the cross-sectional structure of the display device according to the present embodiment.

FIG. 7 is a plan view illustrating an example of a layout of a conductive layer to a pixel in the present embodiment.

FIG. 8 is a plan view illustrating an example of a layout of the conductive layer to a pixel PX in the comparative example of the present embodiment.

FIG. 9 is a plan view illustrating another example of a layout of the conductive layer to the pixel in the present embodiment.

FIG. 10 is a timing chart illustrating an output example of various signals regarding a reset operation of a drive transistor, an offset cancellation operation, a write operation of a pixel signal, and a light emission operation of a light emitting element in the display device according to the present embodiment.

FIG. 11 is a diagram for explaining an outline of the reset operation of the drive transistor.

FIG. 12 is a diagram for explaining an outline of the offset cancellation operation.

FIG. 13 is a diagram for explaining an outline of an image signal write operation.

FIG. 14 is a diagram for explaining an outline of the image signal write operation.

FIG. 15 is a diagram for explaining an outline of a light emitting operation of the light emitting element.

FIG. 16 is a diagram for explaining a timing at which a current starts to flow through the light emitting element.

FIG. 17 is a diagram for explaining the relationship between the output current of the drive transistor and the current flowing through the light emitting element.

FIG. 18 is a diagram for explaining a relationship between a potential rise of a source electrode of the drive transistor and a current flowing through the light emitting element.

FIG. 19 is a view illustrating an example of the cross-sectional structure of the display device in the case in which a common electrode is disposed in the same layer as the pixel electrode.

FIG. 20 is a plan view illustrating an example of a layout of a conductive layer to a pixel in the case in which the pixel electrode and the common electrode are disposed in the same layer.

### DETAILED DESCRIPTION

In general, according to one embodiment, a display device includes a substrate, a pixel electrode disposed on the substrate, a light emitting element mounted on the pixel electrode, a drive transistor configured to control a current supplied to the light emitting element through the pixel electrode, and a conductive layer formed between the pixel electrode and the drive transistor so as to at least partially overlap with the pixel electrode in a planar view. The conductive layer does not overlap with a region of the pixel electrode on which the light emitting element is mounted in a planar view.

Various embodiments will be described hereinafter with reference to the accompanying drawings. The disclosure is merely an example, and appropriate modifications that can be easily conceived by those skilled in the art while maintaining the gist of the invention are naturally included in the scope of the present invention. Furthermore, in order to make the description clearer, the drawings are sometimes schematically represent the width, thickness, shape, and the like of components as compared with the embodiment. However, the drawings are merely examples, and do not limit the interpretation of the present invention. In the drawings, the reference numerals of the same or similar components disposed in succession may be omitted. In addition, in the present specification and the drawings, components that exhibit the same or similar functions as those described above regarding the previously described drawings are designated with the same reference numerals, and redundant detailed description are sometimes appropriately omitted.

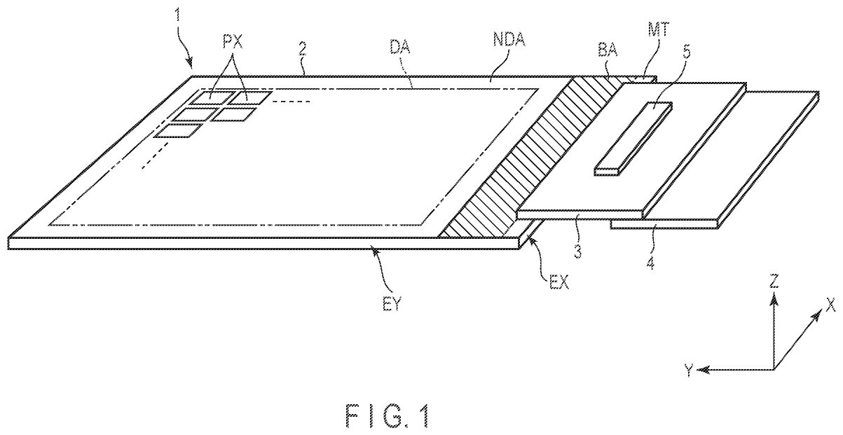

FIG. 1 is a perspective view of the structure of a display device 1 of an embodiment. FIG. 1 illustrates a three dimensional space defined by a first direction X, second direction Y perpendicular to the first direction X, and third direction Z perpendicular to both the first direction X and the second direction Y. Note that the first direction X and the second direction Y are orthogonal to each other; however, they may cross at an angle other than 90°. Furthermore, in the present embodiment, the third direction Z is defined as above, and the opposite direction to the third direction Z is defined as below. A phrase such as a second member above a first member or a second member below a first member may be interpreted as the second member contacting the first member or as the second member being apart from the first member.

In the following, in the present embodiment, the case will be described in which a display device 1 is a micro LED display (micro LED display) using a micro LED that is a self-luminous element.

As illustrated in FIG. 1, the display device 1 includes a display panel 2, a first circuit board 3, a second circuit board 4, and the like.

The display panel 2 has a rectangular shape in one example. In the illustrated example, a short edge EX of the display panel 2 is in parallel with a first direction X, and a long edge EY of the display panel 2 is in parallel with a second direction Y. A third direction Z corresponds to the thickness direction of the display panel 2. The main surface of the display panel 2 is in parallel with an X-Y plane defined by the first direction X and the second direction Y. The display panel 2 includes a display area DA and a non-display area NDA outside the display area DA. The non-display area NDA has a terminal area MT. In the illustrated example, the non-display area NDA surrounds the display area DA.

The display area DA is an area in which an image is displayed, and includes, for example, a plurality of pixels PX disposed in a matrix configuration. The pixel PX includes a light emitting element (micro LED), a switching element (drive transistor) that drives the light emitting element, and the like.

A terminal area MT is provided along the short edge EX of the display panel 2, and includes a terminal that electrically connects the display panel 2 to an external device or the like.

The first circuit board 3 is mounted on the terminal area MT, and electrically connected to the display panel 2. The first circuit board 3 is, for example, a flexible printed circuit board. The first circuit board 3 includes a drive IC chip (in the following, referred to as a panel driver) 5 that drives the display panel 2. In the illustrated example, the panel driver 5 is disposed on the first circuit board 3, but may be disposed below the first circuit board 3. The panel driver 5 may be mounted on other than the first circuit board 3, for example, and may be mounted on the second circuit board 4.

The second circuit board 4 is, for example, a flexible printed circuit board. The second circuit board 4 is connected to the first circuit board 3, for example, below the first circuit board 3.

The panel driver 5 is connected to a control board (not illustrated) through the second circuit board 4, for example. The panel driver 5 performs control that displays an image on the display panel 2 by driving the plurality of pixels PX based on, for example, a video signal output from the control board.

The display panel 2 may have a bend area BA indicated by hatching. The bend area BA is an area that is bent when the display device 1 is housed in the housing of an electronic device or the like. The bend area BA is located on the terminal area MT side of the non-display area NDA. The first circuit board 3 and the second circuit board 4 can be disposed below the display panel 2 so as to face the display panel 2 by bending the bend area BA.

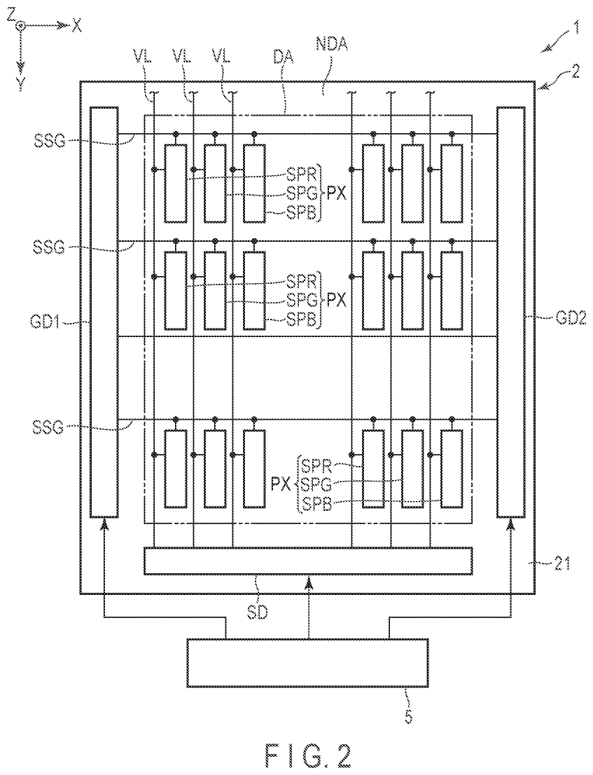

FIG. 2 is a plan view illustrating the circuit configuration of the display device 1. As illustrated in FIG. 2, the display device 1 includes an active matrix-type display panel 2. The display panel 2 includes an insulating substrate 21. On the insulating substrate 21, the plurality of pixels PX, various wires, gate drivers GD1 and GD2, and a selection circuit SD are disposed.

The plurality of pixels PX is arranged in a matrix configuration in the display area DA. The plurality of pixels PX each includes a plurality of sub-pixels. In the present embodiment, the pixel PX includes three types of sub-pixels: a sub-pixel SPR exhibiting a first color, a sub-pixel SPG exhibiting a second color, and a sub-pixel SPB exhibiting a third color. Here, the first color, the second color, and the third color are, for example, red, green, and blue, respectively. The pixel PX includes a light emitting element (micro LED) and a pixel circuit that supplies a drive current to the light emitting element and drives the light emitting element. The pixel circuit includes a drive transistor, various switching elements, and the like described later.

The above-described various wires extend in the display area DA and are drawn out to the non-display area NDA. In FIG. 2, a plurality of control wires SSG and a plurality of image signal lines VL are illustrated as a part of the various wires.

In the display area DA, the control wire SSG and the image signal line VL are connected to the sub-pixels SPR, SPG, and SPB. The control wire SSG is connected to the gate drivers GD1 and GD2 in the non-display area NDA. The image signal line VL is connected to the selection circuit SD in the non-display area NDA.

The gate drivers GD1 and GD2 and the selection circuit SD are located in the non-display area NDA. To the gate drivers GD1 and GD2 and the selection circuit SD, various signals and voltages are supplied from the panel driver 5.

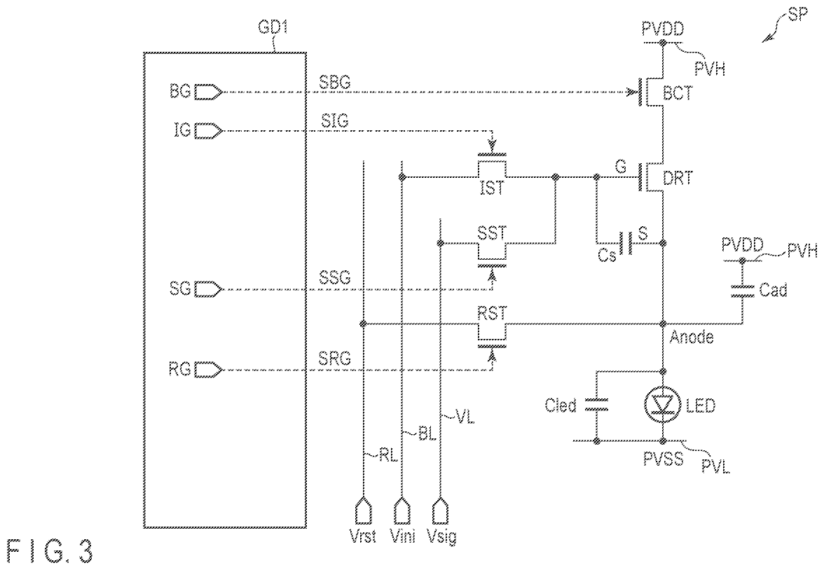

Next, an example of a circuit configuration (pixel circuit) of a pixel in the display device 1 will be described with reference to FIG. 3. In the present embodiment, the plurality of pixels PX is similarly formed. As described above, the pixel PX includes the sub-pixels SPR, SPG, and SPB, and the sub-pixels SPR, SPG, and SPB are similarly formed. Therefore, here, for convenience, a configuration (pixel circuit) of one sub-pixel (in the following, referred to as a sub-pixel SP) of the sub-pixels SPR, SPG, and SPB will be mainly described.

As illustrated in FIG. 3, the sub-pixel SP includes a light emitting element LED, a drive transistor DRT, an output transistor BCT, a pixel transistor SST, an initialization transistor IST, a reset transistor RST, a retention capacitance Cs, and an auxiliary capacitance Cad. In the present embodiment, these are disposed in each sub pixel SP.

The transistors illustrated in FIG. 3 are n-channel transistors. The output transistor BCT, the pixel transistor SST, the initialization transistor IST, and the reset transistor RST do not have to be formed of a transistor. The output transistor BCT, the pixel transistor SST, the initialization transistor IST, and the reset transistor RST only have to be ones that function as an output switch, a pixel switch, an initialization switch, and a reset switch, respectively.

In the following description, one of the source electrode and the drain electrode of the transistor is referred to as a first electrode, and the other is referred to as a second electrode. Further, one electrode of the capacitive element is referred to as a first electrode, and the other electrode is referred to as a second electrode.

The drive transistor DRT, the pixel electrode and the light emitting element LED, described later, are connected in series between a first power supply line PVH and a second power supply line PVL. The first power supply line PVH is retained at a constant potential, and the second power supply line PVL is retained at a constant potential different from the potential of the first power supply line PVH. In the present embodiment, a potential PVDD of the first power supply line PVH is higher than a potential PVSS of the second power supply line PVL. Specifically, the potential PVDD of the first power supply line PVH is, for example, 9 V, and the potential PVSS of the second power supply line PVL is, for example, 0 V.

The first electrode of the drive transistor DRT is connected to the first electrode (anode) of the light emitting element LED, the first electrode of the retention capacitance Cs, and the first electrode of the auxiliary capacitance Cad. The second electrode of the drive transistor DRT is connected to the first electrode of the output transistor BCT. The drive transistor DRT is configured to control a current (current value) supplied to the light emitting element LED.

The second electrode of the output transistor BCT is connected to the first power supply line PVH. The second electrode (cathode) of the light emitting element LED is connected to the second power supply line PVL.

The first electrode of the pixel transistor SST is connected to the gate electrode of the drive transistor DRT, the first electrode of the initialization transistor IST, and the second electrode of the retention capacitance Cs. The second electrode of the pixel transistor SST is connected to the image signal line VL. The second electrode of the initialization transistor IST is connected to an initialization power supply line BL.

The retention capacitance Cs is electrically connected between the gate electrode and the first electrode (source electrode) of the drive transistor DRT. Although details will be described later, in the present embodiment, the value (capacitance size) of the retention capacitance Cs is smaller than the value (capacitance size) of the auxiliary capacitance Cad.

The second electrode of the auxiliary capacitance Cad is retained at a constant potential. In the present embodiment, the second electrode of the auxiliary capacitance Cad is connected to, for example, the first power supply line PVH, and is retained at the same constant potential (PVDD) as the potential of the first power supply line PVH. The second electrode of the auxiliary capacitance Cad may be retained at the same constant potential (PVSS) as the potential of the second power supply line PVL, or may be retained at the same constant potential as the power supply line (third power supply line) different from the first power supply line PVH and the second power supply line PVL. Examples of the third power supply line include the initialization power supply line BL or a reset power supply line RL as wire retained at a constant potential.

The first electrode of the reset transistor RST is connected to the first electrode of the drive transistor DRT. The second electrode of the reset transistor RST is connected to the reset power supply line RL.

To the image signal line VL, an image signal Vsig such as a video signal is supplied. The image signal Vsig is a signal that is written in the pixel (here, the sub pixel SP), the minimum value of the image signal Vsig is, for example, 0 V, and the maximum value of the image signal Vsig is, for example, 3 V.

To the initialization power supply line BL, an initialization potential Vini is supplied. The initialization potential Vini is, for example, 1.2 V.

The reset power supply line RL is set at a reset power supply potential Vrst. The reset power supply potential Vrst is, for example, −2 V to which a potential having such a potential difference that the light emitting element LED does not emit light is applied to PVSS.

The gate electrode of the output transistor BCT is connected to a control wire SBG. To the control wire SBG, an output control signal BG is supplied.

The gate electrode of the pixel transistor SST is connected to the control wire SSG. To the control wire SSG, a pixel control signal SG is supplied.

The gate electrode of the initialization transistor IST is connected to the control wire SIG. To the control wire SIG, an initialization control signal IG is supplied.

The gate electrode of the reset transistor RST is connected to a control wire SRG. To the control wire SRG, a reset control signal RG is supplied.

Note that an element capacitance Cled illustrated in FIG. 3 is a capacitance between the first electrode (anode) and the second electrode (cathode) of the light emitting element LED.

In FIG. 3, it is described that all the transistors are NchTFTs. However, for example, all the transistors other than the drive transistor DRT may be PchTFTs, or NchTFTs and PchTFTs may be mixed.

The drive transistor DRT may be a PchTFT. In that case, a current only has to flow through the light emitting element LED in a direction opposite to the present embodiment. In any case, the auxiliary capacitance Cad may be coupled to the electrode on the drive transistor DRT side among the electrodes of the light emitting element LED.

As described in FIG. 2, since the display device 1 includes two gate drivers GD1 and GD2, it is possible to supply power to one pixel PX (sub-pixel SP) from the gate drivers GD1 and GD2 on both sides. Here, it is assumed that two-way power supply is adopted for the control wire SSG described above, and one-way power supply is adopted for the other control wires. However, the display device 1 does not necessarily have to include the two gate drivers GD1 and GD2, and only has to include at least one gate driver.

The circuit configuration described in FIG. 3 is an example, and the circuit configuration of the display device 1 may be another configuration as long as it includes the drive transistor DRT, the retention capacitance Cs, and the auxiliary capacitance Cad described above. For example, a part of the circuit configuration described in FIG. 3 may be omitted, or another configuration may be added.

Here, although the detailed operation will be described later, the current (micro LED current) flowing through the light emitting element LED when the light emitting element LED emits light in the circuit configuration illustrated in FIG. 3 is defined by the following Formula (1).

$$Idrt = Iled = 1 / 2 Cox * μ * W / L * {\{ ( Vsig - Vini ) * \frac{( Cled + Cad )}{( Cs + Cad + Cled )} \}}^{2} \qquad Formula ( 1 )$$

In Formula (1), Cox is the gate capacitance per unit area, μ is the carrier mobility, W is the channel width of the drive transistor DRT, and L is the channel length of the drive transistor DRT. In addition, Vsig represents the image signal Vsig described above, and is a write voltage value that is written in the sub-pixel SP. Vini represents the above-described initialization potential, and is the gate voltage value of the drive transistor DRT at the time of offset cancellation (Vth correction). In addition, Cs is the value of the above-described retention capacitance Cs, Cad is the value of the above-described auxiliary capacitance (additional capacitance) Cad, and Cled is the value of the above-described element capacitance Cled.

Here, the element capacitance Cled is the capacitance of the area of the light emitting element LED, and is proportional to the size of the light emitting element LED. Therefore, in the case in which the definition of the display device 1 is increased, the size of the light emitting element LED is reduced, and thus the value of the element capacitance Cled is smaller than the value of the retention capacitance Cs.

In the case in which the element capacitance Cled and the retention capacitance Cs have the above-described relationship, it is assumed that the auxiliary capacitance Cad of Formula (1) is considerably smaller than, for example, the retention capacitance Cs, it is sometimes difficult to secure a current necessary for causing the light emitting element LED to emit light. Although it is thought that Vsig in Formula (1) is increased in order to secure a necessary current, the output amplitude of Vsig is limited to the output amplitude of the panel driver, and thus it is sometimes difficult to freely increase Vsig. Therefore, it is important to sufficiently secure the auxiliary capacitance Cad.

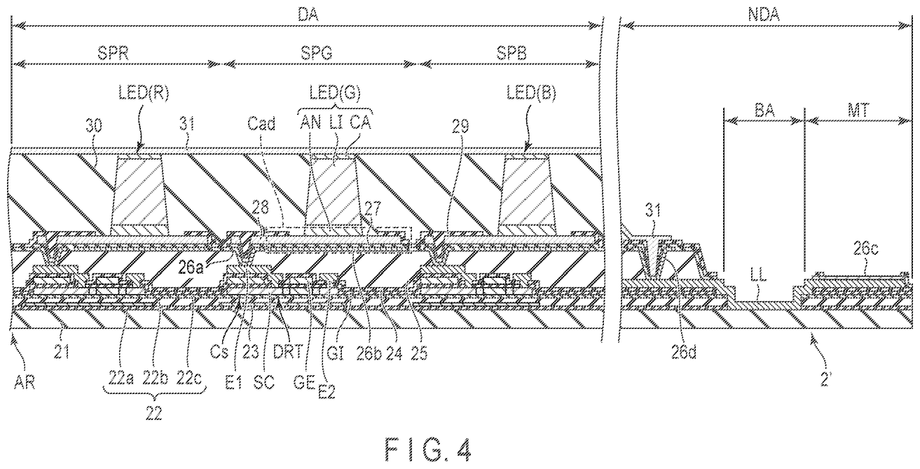

In the following, a comparative example of the present embodiment will be described with reference to FIG. 4. FIG. 4 is a diagram schematically illustrating an example of the cross-sectional structure of a display device according to a comparative example of the present embodiment.

In FIG. 4, it is assumed that the display device according to the comparative example of the present embodiment includes a display panel 2′, and the cross-sectional structure of one pixel PX (sub-pixels SPR, SPG, and SPB) and a non-display area NDA disposed in a display area DA of the display panel 2′ will be mainly described. The non-display area NDA includes a bend area BA that is bent and a terminal area MT.

As illustrated in FIG. 4, an array substrate AR of the display panel 2′ includes an insulating substrate 21. As the insulating substrate 21, a glass substrate such as quartz or alkali-free glass, or a resin substrate such as polyimide can be mainly used. The resin substrate has flexibility, and can form a display device as a sheet display. The resin substrate is not limited to polyimide, and other resin materials may be used. As a result, the insulating substrate 21 may be referred to as an organic insulating layer, a resin layer, or the like.

On the insulating substrate 21, an undercoat layer 22 having a three-layer stacked structure is provided. The undercoat layer 22 includes a first layer 22a made of silicon oxide (SiO2), a second layer 22b made of silicon nitride (SiN), and a third layer 22c made of silicon oxide (SiO2). The first layer 22a that is the lowermost layer is provided as a block film in order to improve adhesion to the insulating substrate 21 that is a base material, and the second layer 22b that is the middle layer is provided as a block film against moisture and impurities from the outside. The third layer 22c that is the uppermost layer is provided as a block film that prevents hydrogen atoms contained in the second layer 22b from diffusing to the semiconductor layer SC side described later.

The undercoat layer 22 is not limited to this structure. The undercoat layer 22 may further have a stack, or may have a single-layer structure or a two-layer structure. For example, in the case in which the insulating substrate 21 is glass, since the silicon nitride film has relatively excellent adhesion, the silicon nitride film may be directly formed on the insulating substrate 21.

On the insulating substrate 21, a light shielding layer 23 is disposed. The position of the light shielding layer 23 is adjusted to a position at which a TFT is formed later. In the present embodiment, although the light shielding layer 23 is formed of, for example, metal, the light shielding layer 23 only has to be formed of a material having a light shielding property such as a black layer.

In the present embodiment, the light shielding layer 23 is provided on the first layer 22a and covered with the second layer 22b. The light shielding layer 23 may be provided on the insulating substrate 21 and covered with the first layer 22a.

According to such a light shielding layer 23, since it is possible to suppress intrusion of light into the back surface of the TFT channel, it is possible to suppress a change in TFT characteristics caused by light that is possibly incident from the insulating substrate 21 side. In the case in which the light shielding layer 23 is formed of a conductive layer, it is also possible to apply a back gate effect to the TFT by applying a predetermined potential to the light shielding layer 23.

On the undercoat layer 22, a thin film transistor (TFT) such as the drive transistor DRT is formed. As the TFT, a polysilicon TFT using polysilicon for the semiconductor layer SC is taken as an example. In the present embodiment, the semiconductor layer SC is formed using low-temperature polysilicon. Here, the drive transistor DRT is an N-channel TFT (NchTFT).

The semiconductor layer SC of the NchTFT includes a first region, a second region, a channel region between the first region and the second region, and low-concentration impurity regions provided between the channel region and the first region and between the channel region and the second region. One of the first and second regions functions as a source region, and the other of the first and second regions functions as a drain region.

As a gate insulating film GI, a silicon oxide film is used. A gate electrode GE is made of MoW (molybdenum/tungsten). Wires and electrodes formed on the gate insulating film GI such as the gate electrode GE are referred to as a first wire or a first metal. The gate electrode GE has a function as a retention capacitance electrode, described later, in addition to a function as a gate electrode of the TFT. Here, although a top gate type TFT is described as an example, the TFT may be a bottom gate type TFT.

On the gate insulating film GI and the gate electrode GE, an interlayer insulating film 24 is provided. The interlayer insulating film 24 is formed by sequentially stacking, for example, a silicon nitride film and a silicon oxide film on the gate insulating film GI and the gate electrode GE.

The gate insulating film GI and the interlayer insulating film 24 are not provided in the bend area BA. In this case, after the gate insulating film GI and the interlayer insulating film 24 are formed in the entire region on the insulating substrate 21 including the bend area BA, the gate insulating film GI and the interlayer insulating film 24 are patterned to remove a portion corresponding to the bend area BA. Since the undercoat layer 22 is exposed by removing the interlayer insulating film 24 and the like, the undercoat layer 22 is also patterned to remove a portion corresponding to the bend area BA. After the undercoat layer 22 is removed, for example, polyimide forming the insulating substrate 21 is exposed. The upper surface of the insulating substrate 21 is sometimes partially eroded or the thickness is sometimes reduced due to the etching of the undercoat layer 22.

In this case, a wire pattern, not illustrated, may be formed below each of the stepped portion at the end portion of the interlayer insulating film 24 and the stepped portion at the end portion of the undercoat layer 22. According to this, a routing wire LL formed in the next step passes over the wire pattern when crossing the stepped portion. Since the gate insulating film GI is provided between the interlayer insulating film 24 and the undercoat layer 22, and the light shielding layer 23 is provided between the undercoat layer 22 and the insulating substrate 21, for example, a wire pattern can be formed using these layers.

On the interlayer insulating film 24, a first electrode E1, a second electrode E2, and the routing wire LL are provided. In the first electrode E1, the second electrode E2, and the routing wire LL, a three-layer stacked structure (Ti-based layer/Al-based layer/Ti-based layer) is adopted. In this three-layer stacked structure, the lower layer is made of Ti (titanium) or a metal material containing Ti as a main component, such as an alloy containing Ti. The intermediate layer is made of Al (aluminum) or a metal material containing Al as a main component, such as an alloy containing Al. The upper layer is made of Ti or a metal material containing Ti as a main component, such as an alloy containing Ti. Note that wires and electrodes formed on the interlayer insulating film 24 such as the first electrode E1 are referred to as second wires or second metals.

The first electrode E1 is connected to the first region of the semiconductor layer SC. The second electrode E2 is connected to the second region of the semiconductor layer SC. For example, in the case in which the first region of the semiconductor layer SC functions as a source region, the first electrode E1 is a source electrode, and the second electrode E2 is a drain electrode. In this case, the first electrode E1 forms the retention capacitance Cs together with the interlayer insulating film 24 and the gate electrode (retention capacitance electrode) GE of the TFT.

The routing wire LL extends to the end portion of the peripheral edge of the insulating substrate 21 and forms a terminal that connects the first circuit board 3 and the panel driver (drive IC) 5. Since the routing wire LL is formed so as to cross the bend area BA and reach the terminal portion, the routing wire LL crosses the step between the interlayer insulating film 24 and the undercoat layer 22. As described above, since the wire pattern of the light shielding layer 23 is formed in the step portion, even though the routing wire LL is cut at the recess of the step, it is possible to maintain the conduction by contacting the lower wire pattern.

A planarization film 25 is formed on the interlayer insulating film 24, the first electrode E1, the second electrode E2, and the routing wire LL so as to cover the TFT and the routing wire LL. As the planarization film 25, an organic insulating material such as photosensitive acrylic is often used. The organic insulating material is excellent in the coverage of wire steps and surface flatness, compared with inorganic insulating materials formed by CVD or the like. The planarization film 25 is removed in the pixel contact part and the peripheral region.

On the planarization film 25, a conductive layer including conductive layers 26a and 26b is provided. The conductive layer is formed of, for example, indium tin oxide (ITO) as an oxide conductive layer.

The conductive layer 26a covers a portion from which the first electrode E1 is exposed by, for example, removing the planarization film 25. One object of the conductive layer 26a is to serve as a barrier film that prevents the exposed part of the first electrode E1 and the routing wire LL from being damaged in the manufacturing process.

Note that a wire or an electrode formed on the planarization film 25 such as the conductive layer 26b is referred to as a third wire or a third metal. In addition, a conductive layer 26c illustrated in FIG. 4 may be formed as a conductive layer forming the surface of the terminal portion.

The planarization film 25 and the conductive layers (conductive layers 26a and 26b) are covered with an insulating layer 27. The insulating layer 27 is formed of, for example, a silicon nitride film. On the insulating layer 27, a pixel electrode 28 is formed on. The pixel electrode 28 is in contact with the insulating layer 26 through the opening of the conductive layer 27a, and electrically connected to the first electrode E1. Here, the pixel electrode 28 serves as a connection terminal that mounts a light emitting element LED (LED chip). The pixel electrode 28 is formed of a single conductive layer or a stack including two or more conductive layers. In the pixel electrode 28, for example, a two-layer stacked structure (Al-based layer/Mo-based layer) is adopted. In this two-layer stacked structure, the lower layer is made of Mo and a metal material containing Mo as a main component, such as an alloy containing Mo. The upper layer is made of Al and a metal material containing Al as a main component, such as an alloy containing Al.

As illustrated in FIG. 4, the conductive layer 26b, the insulating layer 27, and the pixel electrode 28 form the auxiliary capacitance Cad described above.

On the insulating layer 27 and the pixel electrode 28, an insulating layer 29 is provided. The insulating layer 29 is formed of, for example, silicon nitride. The insulating layer 29 insulates the end portion of the pixel electrode 28 and the like, and has an opening that mounts the light emitting element LED on a part of the surface of the pixel electrode 28. The size of the opening of the insulating layer 29 is slightly larger than that of the light emitting element LED in consideration of the mounting deviation amount and the like in the mounting process of the light emitting element LED. For example, in the case in which the light emitting element LED has a mounting area of substantially 10 μm×10 μm, preferably, the area of substantially 20 μm×20 μm is secured for the opening.

In the display area DA, the light emitting element LED is mounted on the array substrate AR (pixel electrode 28). The light emitting element LED includes an anode AN, a cathode CA, and a light emitting layer LI that emits light. The anode AN and the cathode CA are disposed at positions facing each other with the light emitting layer LI being interposed.

The light emitting element LEDs having R, G, and B emission colors are prepared, and an anode-side terminal is in contact with and fixed to the corresponding pixel electrode 28. In the example illustrated in FIG. 4, a light emitting element LED having a red emission color is illustrated as an LED (R), a light emitting element LED having a green emission color is illustrated as an LED (G), and a light emitting element LED having a blue emission color is illustrated as an LED (B). In other words, the light emitting element LED (R) is a light emitting element LED included in the sub-pixel SPR, the light emitting element LED (G) is a light emitting element LED included in the sub-pixel SPG, and the light emitting element LED (B) is a light emitting element LED included in the sub-pixel SPB.

The bonding between the anode AN of the light emitting element LED and the pixel electrode 28 is not specifically limited as long as excellent conduction can be secured between the anode AN and the pixel electrode, and the formed object of the array substrate AR is not damaged. For example, a reflow process using a low-temperature melting solder material, a method of placing the light emitting element LED on the array substrate AR through a conductive paste and then burning and bonding the light emitting element LED, or a method of solid layer bonding such as ultrasonic bonding using a similar material for the surface of the pixel electrode 28 and the anode AN of the light emitting element LED can be adopted.

On the array substrate AR on which the light emitting element LEDs are mounted, an element insulating layer 30 is provided. The element insulating layer 30 is formed of a resin material filling voids between the light emitting elements LED on the array substrate AR. The element insulating layer 30 exposes the surface of the cathode CA of the light emitting element LED.

A counter electrode 31 is disposed at a position facing the pixel electrode 28 through the light emitting element LED. The counter electrode 31 is formed on the surface of the cathode CA of the counter electrode 31 and the element insulating layer 30, and electrically connected to the cathode CA, being in contact with the cathode CA. The counter electrode 31 has to be formed as a transparent electrode in order to extract light emitted from the light emitting element LED. The counter electrode 31 is formed using, for example, ITO as a transparent conductive material. The counter electrode 31 commonly connects the cathodes CA of the plurality of light emitting element LEDs mounted in the display area DA. Although not illustrated, the counter electrode 31 is connected to the wire provided on the array substrate AR side by, for example, a cathode contact part provided outside the display area DA.

The counter electrode 31 is formed so as to cover the display area DA in a planar view, extends to the non-display area NDA, and is electrically connected to the conductive layer 26d. The conductive layer 26d is conducted with the second power supply line PVL.

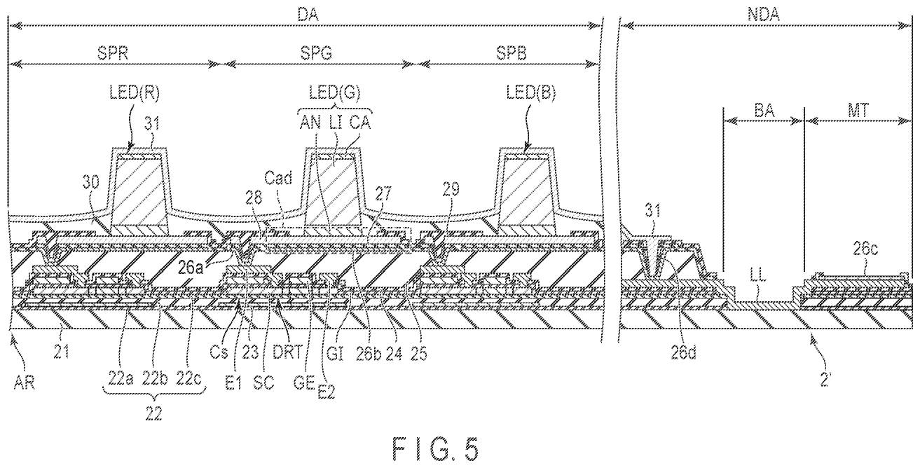

On the other hand, in the case in which the side wall portion of the light emitting element LED is insulated by a protective film or the like, the gap is not necessarily filled with a resin material or the like, and the resin material only has to insulate at least the anode AN and the surface of the pixel electrode 28 exposed from the anode AN. In this case, as illustrated in FIG. 5, the element insulating layer 30 is formed with a film thickness that does not reach the cathode CA of the light emitting element LED, and subsequently the counter electrode 31 is formed. Although a part of the unevenness due to the mounting of the light emitting element LED remains on the surface on which the counter electrode 31 is formed, it is sufficient that the material forming the counter electrode 31 can be continuously covered without disconnection.

As described above, although the array substrate AR has a structure from the insulating substrate 21 to the counter electrode 31, a cover member such as a cover glass, a touch panel substrate, or the like may be provided on the counter electrode 31 as necessary. The cover member and the touch panel substrate may be provided through a filler using resin or the like, for example.

Although the display device (the display panel 2′) according to the comparative example of the present embodiment is described with reference to FIG. 4, it is necessary to secure a sufficient auxiliary capacitance Cad in the display device as described above. Although the auxiliary capacitance Cad is formed by the conductive layer 26b, the insulating layer 27, and the pixel electrode 28 as described in FIG. 4, in order to secure a sufficient auxiliary capacitance Cad, it is preferable to increase the area of the conductive layer 26b (third metal) overlapping with the pixel electrode 28 in a planar view. Therefore, in the display device according to the comparative example of the present embodiment, the conductive layer 26b is formed, for example, in a region other than the contact part electrically connecting the pixel electrode 28 and the first electrode E1 (drive transistor DRT) as illustrated in FIG. 4.

However, in the configuration of the display device according to the comparative example of the present embodiment, when the light emitting element LED (LED chip) is mounted on the array substrate AR (pixel electrode 28) as described above, the array substrate AR is likely to be damaged, and a point defect may occur. Specifically, in the display device according to the comparative example of the present embodiment, the conductive layer 26b connected to the DC power supply (first power supply line PVH) is disposed immediately below the pixel electrode 28. However, the insulating layer 27 provided between the conductive layer 26b and the pixel electrode 28 is thin, and there is a possibility that the pixel electrode 28 and the conductive layer 26b are short-circuited due to the pressing of the LED chip when the light emitting element LED is mounted.

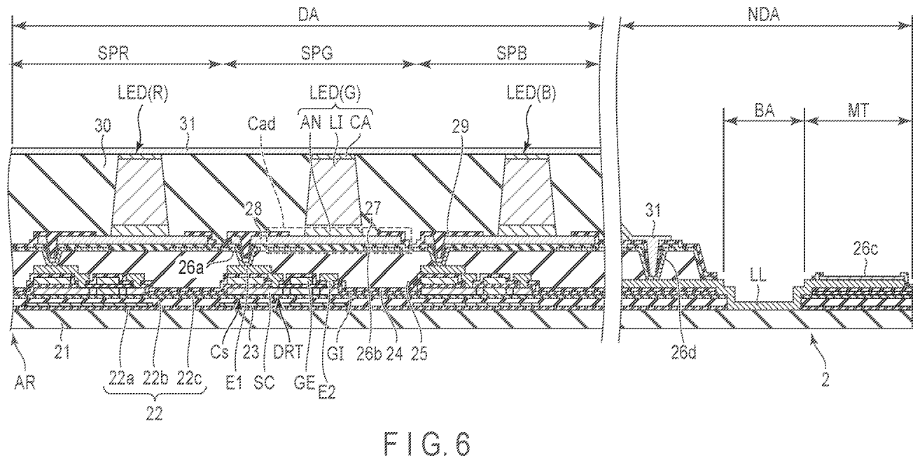

Therefore, in the display device 1 according to the present embodiment, as illustrated in FIG. 6, the conductive layer 26b is formed so as not to overlap with the region (in the following, referred to as a mounting region of the light emitting element LED) of the pixel electrode 28 on which the light emitting element LED is mounted in a planar view.

Although FIG. 6 illustrates the cross-sectional structure of the display device 1 according to the present embodiment, the cross-sectional structure is similar to that of FIG. 4 except the above-described conductive layer 26b, and thus a detailed description will be omitted here.

The present embodiment may be applied to the cross-sectional structure illustrated in FIG. 5. In this case, the conductive layer 26b illustrated in FIG. 5 only has to be formed so as not to overlap with the mounting region of the light emitting element LED in a planar view.

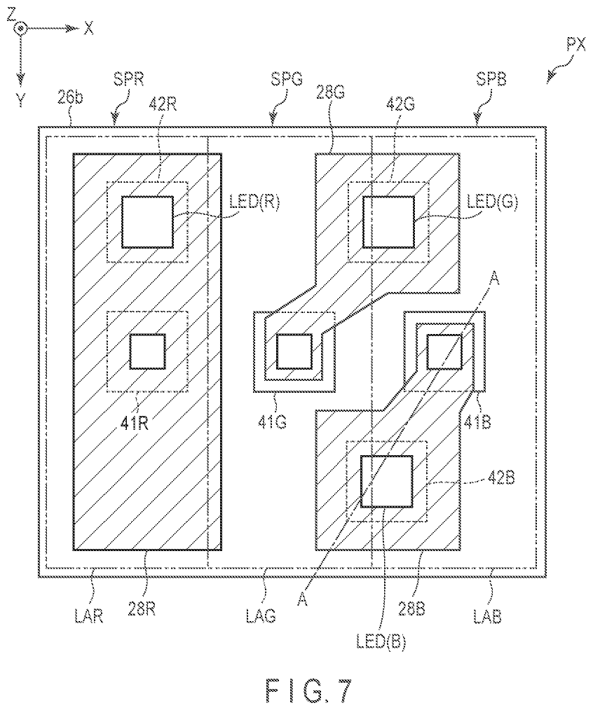

Here, FIG. 7 is a plan view illustrating an example of a layout (shape) of the conductive layer 26b to the pixel PX (the sub-pixels SPR, SPG, and SPB) in the present embodiment.

As illustrated in FIG. 7, the pixel PX including the sub-pixels SPR, SPG, and SPB shares a single conductive layer 26b. In other words, the conductive layer 26b is formed so as to continuously extend over the plurality of sub-pixels SPR, SPG, and SPB (the plurality of pixels PX). As described above, the conductive layer 26b is located below the pixel electrode 28.

In FIG. 7, the pixel electrode 28 (i.e., the pixel electrode 28 connected to the light emitting element LED (R) of the sub-pixel SPR) included in the sub-pixel SPR is referred to as a pixel electrode 28R for convenience. The pixel electrode 28 (i.e., the pixel electrode 28 connected to the light emitting element LED (G) of the sub-pixel SPG) included in the sub-pixel SPG is referred to as a pixel electrode 28G for convenience. Similarly, the pixel electrode 28 (i.e., the pixel electrode 28 connected to the light emitting element LED (B) of the sub-pixel SPB) included in the sub-pixel SPB is referred to as a pixel electrode 28B for convenience.

In a planar view in FIG. 7, the pixel electrode 28R is formed in a rectangular shape. The pixel electrodes 28G and 28B are formed in a non-rectangular shape. The pixel electrodes 28R, 28G, and 28B are formed such that the size of the pixel electrode 28R is the largest and the sizes of the pixel electrodes 28G and 28B are the same. The sizes of the pixel electrodes 28G and 28B may be different from each other.

Furthermore, arrangement regions LAR, LAG, and LAB are disposed in the first direction X. Here, the arrangement region LAR is a region in which the remaining elements other than the auxiliary capacitance Cad (pixel electrode 28R), for example, in the pixel circuit of the sub-pixel SPR are disposed. The arrangement region LAG is a region in which the remaining elements other than the light emitting element LED (G) and the auxiliary capacitance Cad (pixel electrode 28G) are disposed, for example, in the pixel circuit of the sub-pixel SPG. The arrangement region LAB is a region in which the remaining elements other than the light emitting element LED (B) and the auxiliary capacitance Cad (pixel electrode 28B) are disposed, for example, in the pixel circuit of the sub-pixel SPB.

In the example illustrated in FIG. 7, the light emitting element LED (R) is located in the arrangement region LAR, and the light emitting element LED (G) and the LED (B) are located across the arrangement regions LAG and LAB, respectively. The pixel electrode 28R is located in the arrangement region LAR and further located in the arrangement region LAG. The pixel electrodes 28G and 28B are located in the arrangement regions LAG and LAB. The pixel electrode 28 (28R, 28G, and 28B) may be provided so as to be located in the arrangement region of the adjacent pixel PX.

As illustrated in FIG. 7, the conductive layer 26b has openings 41R, 41G, and 41B. The opening 41R is an opening formed in the conductive layer 26b in order to contact the pixel electrode 28R with the first electrode E1 (drive transistor DRT) included in the sub-pixel SPR. The opening 41G is an opening formed in the conductive layer 26b in order to contact the pixel electrode 28G with the first electrode E1 (drive transistor DRT) included in the sub-pixel SPG. The opening 41B is an opening formed in the conductive layer 26b in order to contact the pixel electrode 28B with the first electrode E1 (drive transistor DRT) included in the sub-pixel SPB. In the example illustrated in FIG. 7, the openings 41R, 41G, and 41B (i.e., the contact part electrically connecting each of the pixel electrodes 28R, 28G, and 28B and the drive transistor DRT to each other) are disposed linearly extending in the first direction X.

The conductive layer 26b has openings 42R, 42G, and 42B. The opening 42R is an opening formed in the conductive layer 26b such that the conductive layer 26b does not overlap with the mounting region of the light emitting element LED (R) of the sub-pixel SPR. The opening 42G is an opening formed in the conductive layer 26b such that the conductive layer 26b does not overlap with the mounting region of the light emitting element LED (G) of the sub-pixel SPG. The opening 42B is an opening formed in the conductive layer 26b such that the conductive layer 26b does not overlap with the mounting region of the light emitting element LED (B) of the sub-pixel SPB.

In the example illustrated in FIG. 7, the opening 42R is formed slightly larger than the mounting region of the light emitting element LED (R) in a planar view. The opening 42R may be formed to have, for example, the same size as the opening (the opening for mounting the light emitting element LED (R)) provided in the insulating layer 29 described above.

The opening 42R only has to be formed larger than at least the mounting region of the light emitting element LED (R). The opening 42R only has to be formed such that the conductive layer 26b does not overlap with the mounting region of the light emitting element LED (R) and the end portion of the mounting region does not intersect with the end portion of the conductive layer 26b (opening 42R). Here, the opening 42R is described, and the same applies to the openings 42G and 42B.

In the example illustrated in FIG. 7, at least one of the openings 42R, 42G, and 42B (i.e., the mounting region of the light emitting element LED (R), the LED (G), and the LED (B)) is formed so as not to be linearly disposed. Specifically, although the openings 42R and 42G are disposed linearly extending in the first direction X, the opening 42B is not disposed linearly extending in the first direction X. Although the openings 42G and 42B are disposed linearly extending in the second direction Y, the opening 42R is not disposed linearly extending in the second direction Y.

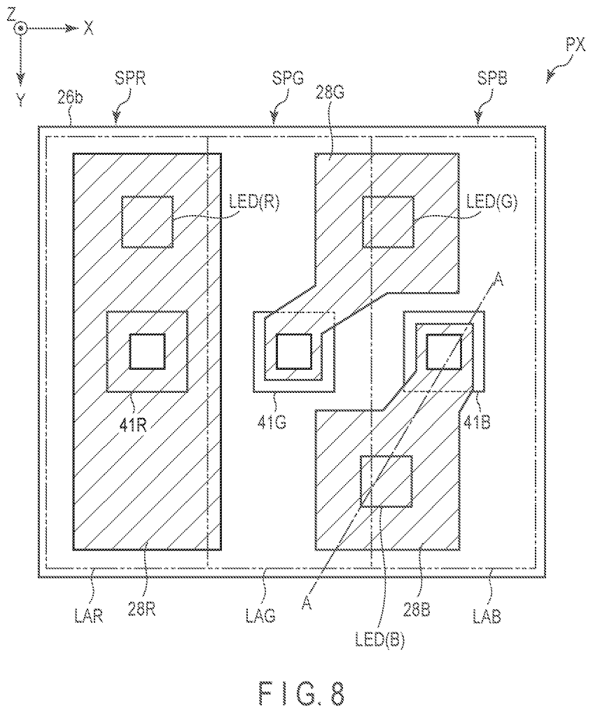

Here, FIG. 8 illustrates an example of a layout (shape) of the conductive layer 26b to the pixel PX the sub-pixels SPR, SPG, and SPB) in a comparative example of the present embodiment. In the present embodiment, compared with the comparative example of the present embodiment illustrated in FIG. 8, since the openings 42R, 42G, and 42B are formed so as to cut out the conductive layer 26b immediately below the mounting region of each of the light emitting element LED (R), the LED (G), and the LED (B), it is possible to suppress a situation in which a short circuit occurs between the pixel electrode 28 (28R, 28G, and 28B) and the conductive layer 26b when the light emitting element LED is mounted.

The sizes of the openings 42R, 42G, and 42B illustrated in FIG. 7 may be the same or different. The sizes of the openings 42R, 42G, and 42G may be determined based on, for example, the sizes of the light emitting element LED (R), the LED (G), and the LED (B) (i.e., the LED chip mounted on the pixel electrodes 28R, 28G, and 28B).

Here, the value (size) of the auxiliary capacitance Cad is proportional to the area of the conductive layer 26b overlapping with the pixel electrode 28. Therefore, as illustrated in FIG. 7, in the case in which the pixel electrode 28R is larger than the pixel electrodes 28G and 28B, the auxiliary capacitance Cad in each of the sub-pixels SPG and SPB is smaller than the auxiliary capacitance Cad in the sub-pixel SPR.

Therefore, for example, priority is given to suppressing the occurrence of the point defect (i.e., a short circuit between the pixel electrode 28R and the conductive layer 26b) by forming the opening 42R so as to have a relatively large size, and the openings 42G and 42B are formed so as to have a relatively smaller size than the opening 42R, and thus the occurrence of the point defect may be suppressed to the minimum and the auxiliary capacitance Cad may be secured to the maximum. That is, in the present embodiment, the sizes of the openings 42R, 42G, and 42B may be determined according to the emission color of the light emitting element LED mounted on the pixel electrode 28, the size of the pixel electrode 28, or the like. In order to secure the auxiliary capacitance Cad, the sizes of the pixel electrodes 28R, 28G, and 28B may be designed to be increased according to the sizes of the openings 42R, 42G, and 42B.

FIG. 6 illustrates the cross-sectional structure of the display device 1 according to the present embodiment, and for example, a portion corresponding to the sub-pixel SPB illustrated in FIG. 6 illustrates a cross-sectional structure (i.e., the cross-sectional structure including the openings 41B and 42B) along line A-A illustrated in FIG. 7. Although not illustrated in FIG. 7, the same applies to the sub-pixels SPR and SPG.

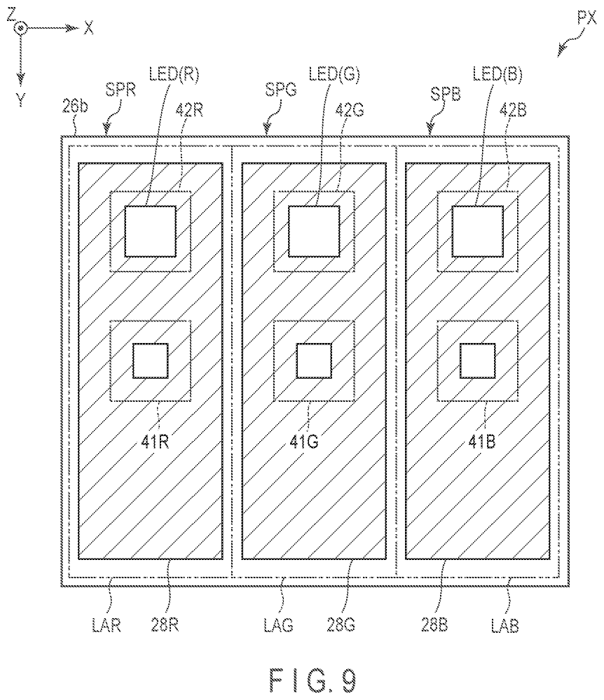

In addition, a layout of the conductive layer 26b illustrated in FIG. 7 described above is an example, and the conductive layer 26b may be formed as illustrated in FIG. 9, for example. In the example illustrated in FIG. 9, the pixel electrodes 28R, 28G, and 28B are each formed in a rectangular shape, and are disposed side by side (in a stripe shape) in the first direction X.

In a planar view in FIG. 9, the openings 41R, 41G, and 41B (i.e., the contact part electrically connecting each of the pixel electrodes 28R, 28G, and 28B and the drive transistor DRT to each other) are disposed linearly extending in the first direction X.

The openings 42R, 42G, and 42B (i.e., the mounting region of each of the light emitting element LED (R), the LED (G), and the LED (B)) are disposed linearly extending in the first direction X.

In the present embodiment, even in the case in which the pixel electrodes 28R, 28G, and 28B are disposed as illustrated in FIG. 9, the openings 42R, 42G, and 42B are formed in the conductive layer 26b, and thus a situation in which the pixel electrode 28 (28R, 28G, and 28B) and the conductive layer 26b are short-circuited can be suppressed.

According to the configuration illustrated in FIG. 9, for example, since at least the pixel electrodes 28G and 28B can be made larger than the case illustrated in FIG. 7, the auxiliary capacitance Cad in the sub-pixels SPG and SPB can be secured. In this case, since the openings 42G and 42B can be formed with a size having a margin, it is possible to improve the reliability of suppressing the occurrence of defects at the time of mounting the light emitting element LED.

In FIG. 9, for example, although the openings 42R, 42G, and 42B are linearly disposed, the openings 42R, 42G, and 42B may be disposed in a V shape, for example.

In the following, an operation in the display device 1 (pixel circuit illustrated in FIG. 3) will be described. In the circuit configuration illustrated in FIG. 3 described above, the reset control signal RG is input to the first electrode (source electrode) of the drive transistor DRT, and thus the reset is performed without passing through the drive transistor DRT. In order to avoid the occurrence of a short circuit between anodes, the reset transistor is disposed for each pixel, not in the driver. For example, in the case of a configuration in which one output transistor BCT is disposed for three sub-pixels SPR, SPG, and SPB, the anodes are connected through the drive transistors DRT of the respective sub-pixels at the time of signal writing (without mobility correction), and signal color mixture may occur among R, G, and B. Therefore, in the present embodiment, the output transistor BCT is disposed for each sub pixel.

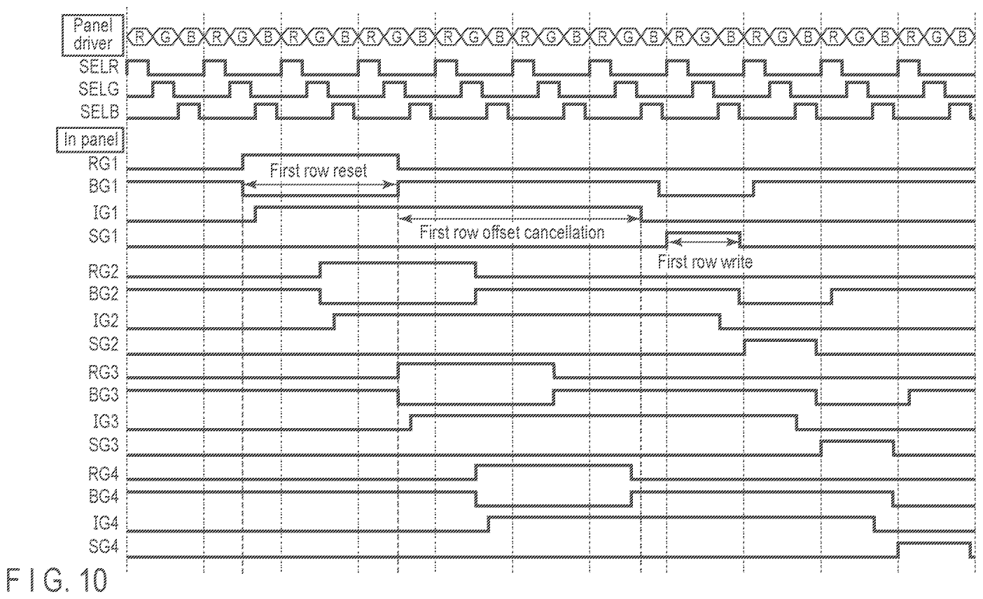

FIG. 10 is a timing chart illustrating an output example of various signals related to a reset operation, an offset cancellation (OC) operation, a write operation, and a light emission operation in the display device 1. Here, signals supplied to the control wires SRG, SBG, SIG, and SSG will be mainly described.

The operations described above are performed in units of rows of the pixels PX. In FIG. 10, the reset control signal supplied to the control wire SRG connected to the pixel PX in the first row is denoted as RG1, the output control signal supplied to the control wire SBG is denoted as BG1, the initialization control signal supplied to the control wire SIG is denoted as IG1, and the pixel control signal supplied to the control wire SSG is denoted as SG1.

In FIG. 10, the reset control signal supplied to the control wire SRG connected to the pixel PX in the second row is denoted as RG2, the output control signal supplied to the control wire SBG is denoted as BG2, the initialization control signal supplied to the control wire SIG is denoted as IG2, and the pixel control signal supplied to the control wire SSG is denoted as SG2.

Although detailed description is omitted, the same applies to the control signals supplied to the control wires connected to the pixels PX in the third and fourth rows illustrated in FIG. 10. FIG. 10 illustrates timings of the control signals for the pixels PX in the first to fourth rows, and the same applies to the pixels PX in the fifth and subsequent rows.

In the following, control signals related to the reset operation, the offset cancellation operation, the image signal write operation, and the light emission operation of the pixels PX in the first row will be described. The details of each operation will be described later. The reset operation, the offset cancellation operation, the write operation, and the light emission operation in each pixel PX are executed by selecting one of the pixels SPR, SPG, and SPB (RGB) according to the signal (SELR/G/B) output from the panel driver 5.

In the circuit configuration of the display device 1, it is assumed that all the transistors are NchTFTs, and in the case in which a low (L) level signal is supplied to the gate electrode of such a transistor, the transistor is turned into the OFF state (non-conductive state). On the other hand, when a high (H) level signal is supplied to the gate electrode of such a transistor, the transistor is turned into the ON state (conductive state).

First, prior to the reset operation of the retention capacitance Cs, the output control signal BG1 changes from H level to L level, and the reset control signal RG1 changes from L level to H level. As a result, the current between the first power supply line PVH and the second power supply line PVL through the output transistor BCT is blocked, and the space between the output transistor BCT and the anode AN of the light emitting element LED is reset at the reset power supply potential Vrst of the reset wire (the wire connected to the first electrode of the reset transistor RST).

Subsequently, the initialization control signal IG1 changes from L level to H level. In this case, the initialization transistor IST is turned into the ON state, the initialization power supply line BL of the initialization potential Vini and the retention capacitance Cs are conducted, and the retention capacitance Cs is reset at the initial overpotential (Vini).

The output control signal BG1 whose signal is at L level prior to the reset of the retention capacitance Cs becomes H level with the completion of the reset period of the retention capacitance Cs. The reset control signal RG1 becomes L level with the completion of the reset period of the retention capacitance Cs.

The initialization control signal IG1 becomes L level with the completion of the offset cancellation period.

After that the pixel control signal SG1 changes from L level to H level. In this case, a current corresponding to the image signal Vsig flows through the pixel transistor SST to the retention capacitance Cs or the like through the image signal line VL, and a charge corresponding to the image signal Vsig is accumulated in the retention capacitance Cs. As a result, the write operation to the pixels PX (PIXEL PSR, SPG, and SPB) in the first row is completed.

In the case in which the write operation is completed, a current flows through the light emitting element LED according to the current value determined based on the image signal Vsig, and thus the light emitting element LED emits light.

Here, the control signals related to the reset operation, the offset cancellation operation, the write operation, and the light emission operation of the pixels PX in the first row are described, and the same applies to each operation (control signal) in the pixels PX in the second and subsequent rows.

It is assumed that the writing of the image signal Vsig is performed within 1H (horizontal scanning period of one row). It is assumed that the reset operation and the offset cancellation operation are performed in parallel with the writing of the preceding pixel. The reset operation and the offset cancellation operation are ended before the write operation of the image signal Vsig, but the timing of writing the image signal Vsig is substantially the same as that of the liquid crystal display device (LCD), for example. The adjustment of the period during which the reset operation is performed and the period during which the offset cancellation operation is performed is independent of the write operation of the image signal Vsig, and thus has a degree of freedom is high.

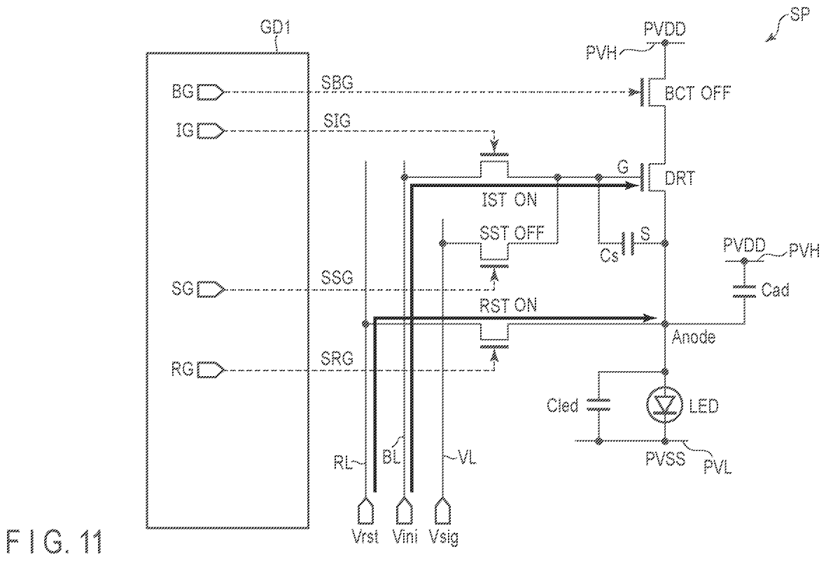

In the following, an outline of the operation of the display device 1 will be described with reference to FIGS. 11 to 16. In the description below, it is assumed that the first electrode of the drive transistor DRT connected to the first electrode of the retention capacitance Cs described above is a source electrode, and the second electrode of the drive transistor DRT connected to the first electrode of the output transistor BCT is a drain electrode.

First, an outline of a reset operation of the drive transistor DRT will be described with reference to FIG. 11.

As illustrated in FIG. 11, in the case of the reset operation of the drive transistor DRT, the output control signal BG and the pixel control signal SG are set to L level, and the initialization control signal IG and the reset control signal RG are set to H level.

According to this, the output transistor BCT is in the OFF state (BCT=OFF), the pixel transistor SST is in the OFF state (SST=OFF), the initialization transistor IST is in the ON state (IST=ON), and the reset transistor RST is in the ON state (RST=ON). That is, in this case, the initialization transistor IST and the reset transistor RST are switched to the ON state.

In such a reset operation of the drive transistor DRT, the source potential of the drive transistor DRT is set to the reset power supply voltage Vrst (e.g. −2 V), and the gate potential of the drive transistor DRT is set to the initialization potential Vini (e.g. 1.2 V), and thus the drive transistor DRT is turned into the ON state, and the source electrode of the drive transistor DRT is charged with the reset power supply voltage Vrst. Note that a current Iled flowing through the light emitting element LED by the application of the reset power supply voltage Vrst is zero.

As a result, the information of the previous frame is reset, and preparation for the offset cancellation operation is completed.

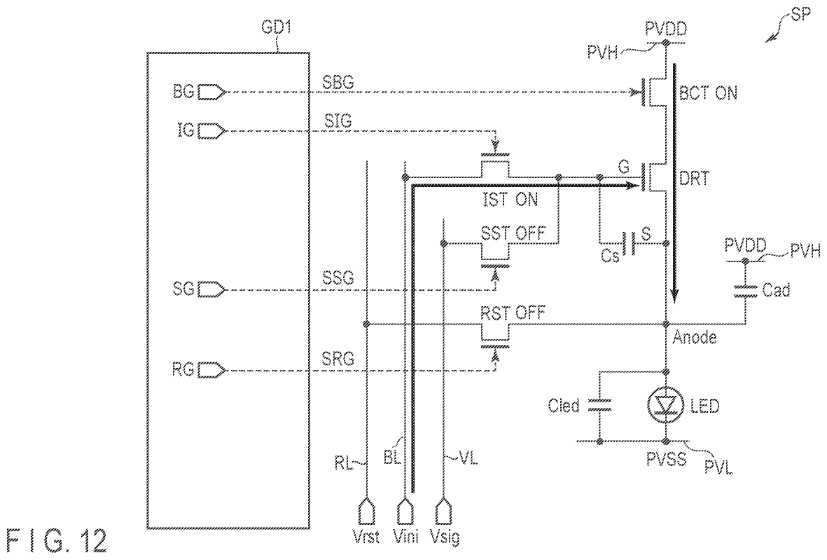

Next, an outline of the offset cancellation operation will be described with reference to FIG. 12. As illustrated in FIG. 12, in the case of the offset cancellation operation, the output control signal BG is switched from L level to H level, and the reset control signal RG is switched from H level to L level. According to this, the output transistor BCT is switched to the ON state, and the reset transistor RST is switched to the OFF state.

In this case, a current flows into the drain electrode of the drive transistor DRT from the first power supply line PVH through the output transistor BCT.

Here, since the drive transistor DRT is in the ON state, the current supplied to the drain electrode of the drive transistor DRT flows through the channel of the drive transistor DRT, and the potential of the source electrode of the drive transistor DRT increases. After that when the difference between the potential of the source electrode and the potential of the gate electrode of the drive transistor DRT reaches the threshold voltage (Vth) of the drive transistor DRT, the drive transistor DRT goes into an OFF state. In other words, the voltage between the gate electrode and the source electrode of the drive transistor DRT converges to a voltage substantially equal to the threshold value of the drive transistor DRT, and the potential difference corresponding to the threshold value is retained in the retention capacitance Cs.

Specifically, the initialization potential (Vini) is supplied to the gate electrode of the drive transistor DRT, and when the potential of the source electrode of the drive transistor DRT reaches Vini-Vth, the drive transistor DRT is turned into the OFF state. As a result, an offset corresponding to the variation in Vth of the drive transistor DRT is generated between the gate electrode and the source electrode of the drive transistor DRT. As a result, the threshold offset cancellation operation of the drive transistor DRT is completed.

As described above, the offset cancellation operation is performed to retain the threshold value (Vth) of the drive transistor DRT between the gate electrode and the source electrode of the drive transistor DRT.

In the case in which the potential PVSS of the second power supply line PVL is 0 V, the potential Vled between the anode and the cathode of the light emitting element LED (between the source electrode of the drive transistor DRT and the second power supply line PVL) is Vled=Vini−Vth. In this case, Vini (initialization potential) is adjusted such that Vled does not exceed the threshold value (Vth−LED) of the light emitting element LED.

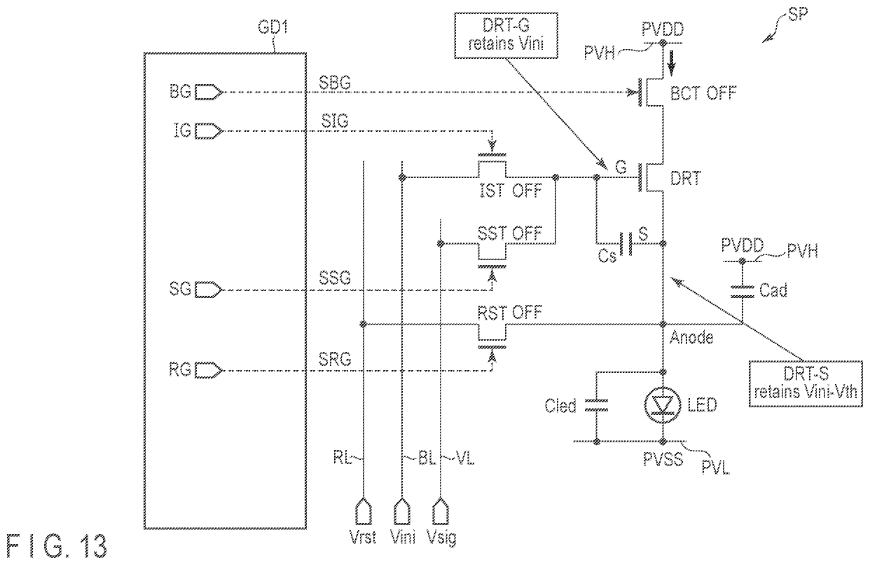

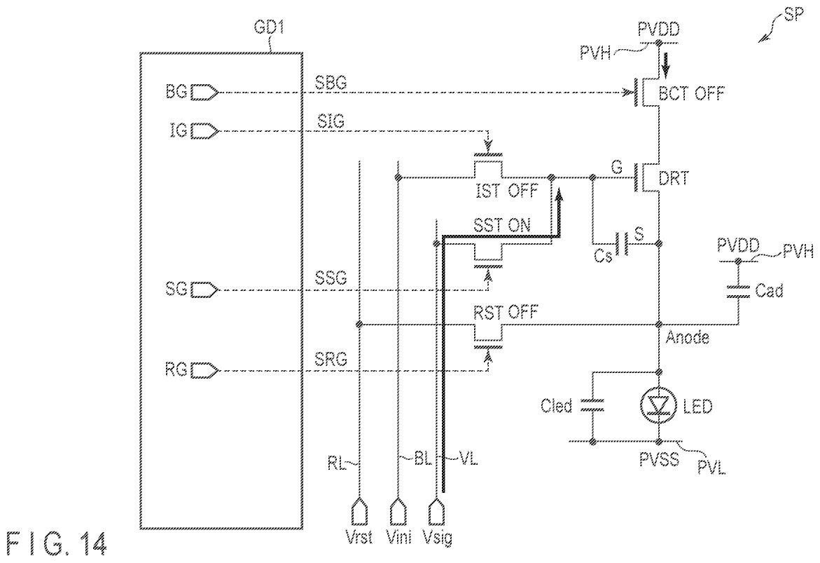

Next, an outline of the write operation of the image signal (video signal) Vsig will be described with reference to FIGS. 13 and 14.

As illustrated in FIG. 13, before the write operation of the image signal Vsig, the output control signal BG and the initialization control signal IG are switched from H level to L level, and thus the output transistor BCT and the initialization transistor IST are each switched to the OFF state. As a result, the current path from the first power supply line PVH (PVDD) to the source electrode of the drive transistor DRT is cut off.

In this case, the gate electrode of the drive transistor DRT retains Vini, and the source electrode of the drive transistor DRT retains Vini-Vth. According to this, the voltage (Vgs) between the gate electrode and the source electrode of the drive transistor DRT is Vth (DRT).

In the case of the write operation of the image signal Vsig, as illustrated in FIG. 14, the pixel control signal SG is switched from L level to H level.

According to this, the pixel transistor SST is switched to the ON state. In this case, the image signal Vsig is written into the gate electrode of the drive transistor DRT through the pixel transistor SST. For example, the voltage value of the image signal Vsig is a value within a range of 0 to 3 V. In the present embodiment, the dynamic range of the image signal Vsig is the same in the sub-pixels SPR, SPG, and SPB.

Here, since the source electrode of the drive transistor DRT has a different potential for each value of Vth due to the offset cancellation operation described above, the voltage Vgs of the drive transistor DRT is different even in the case in which the same image signal Vsig is written. In the drive transistor DRT in which the writing of the image signal Vsig is completed, the voltage Vgs is expressed by Formula (2) below.

$$Vgs = ( Vsig - Vini ) \times \frac{( Cled + Cad )}{( Cs + Cad + Cled )} + Vth \qquad Formula ( 2 )$$

In the write operation described above, since the output transistor BCT is in the OFF state, the light emitting element LED is not turned on (emitted).

Also during the write operation, Vini is adjusted so as not to exceed the threshold value (Vth−LED) of the light emitting element LED described above.

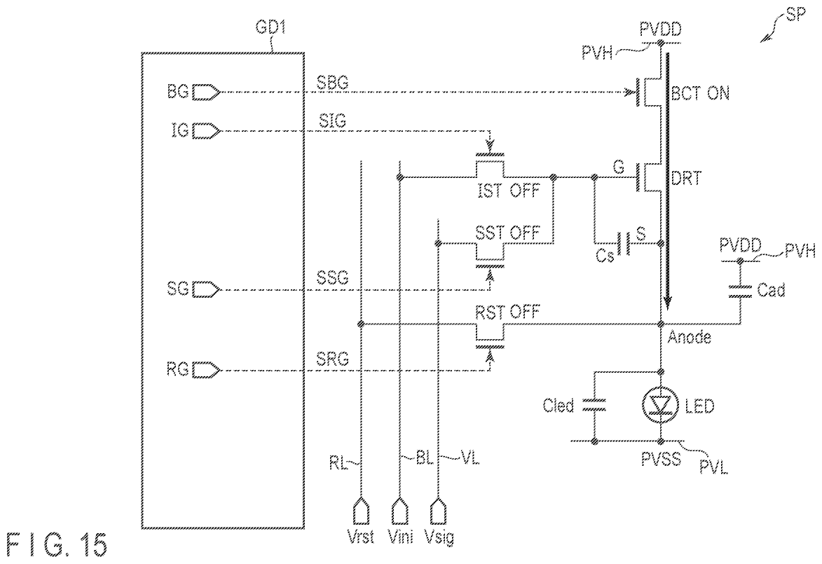

Next, an outline of a light emitting operation for causing the light emitting element LED to emit light will be described with reference to FIG. 15. In the case of the light emitting operation, the output control signal BG is switched from L level to H level, and the pixel control signal SG is switched from H level to L level. According to this, the output transistor BCT is switched to the ON state, and the pixel transistor SST is switched to the OFF state.

As a result, a current starts to flow from the first power supply line PVH (PVDD) to the drive transistor DRT, and the potential of the source electrode of the drive transistor DRT starts to rise.

Here, since the gate electrode of the drive transistor DRT is floating, Vgs is constant. In this case, the potential of the gate electrode of the drive transistor DRT also starts to rise. This phenomenon is referred to as bootstrap.

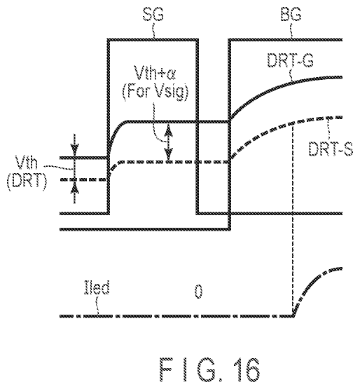

In the light emitting operation, as illustrated in FIG. 16, when the voltage (Vled) between the source electrode of the drive transistor DRT and PVSS becomes equal to or higher than Vth−LED, the current Iled starts to flow through the light emitting element LED. The light emitting element LED is turned on (emits light) by the current Iled.

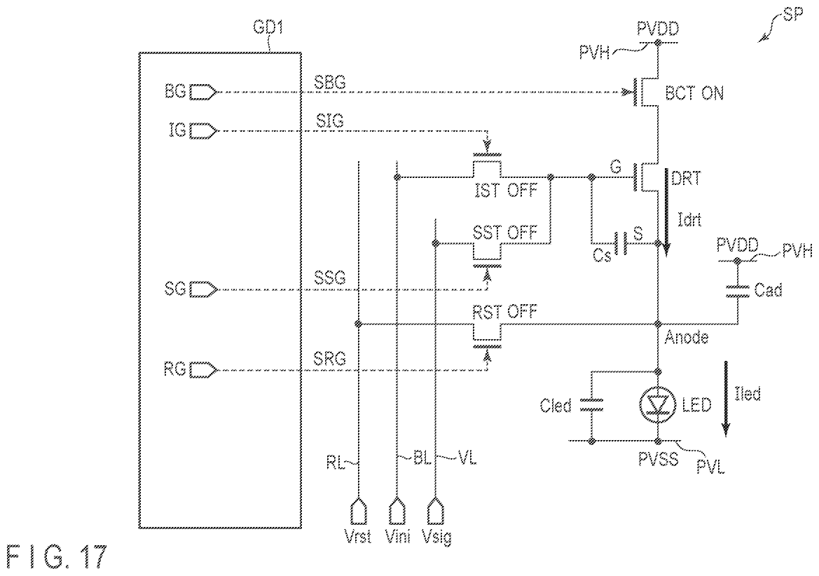

As illustrated in FIG. 17, the current Iled in the light emitting operation (light emitting period) corresponds to the output current (output current of the saturation region of the drive transistor DRT) Idrt supplied from the drive transistor DRT (Iled=Idrt).

Here, the potential (DRT-S) of the source electrode (anode of the light emitting element LED) of the drive transistor DRT at the end of the write operation is expressed as

$$DRT - S ( Anode ) = Vini - Vth + ( Vsig - Vini ) * \frac{( Cs )}{( Cs + Cad + Cled )} \qquad Formula ( 3 )$$

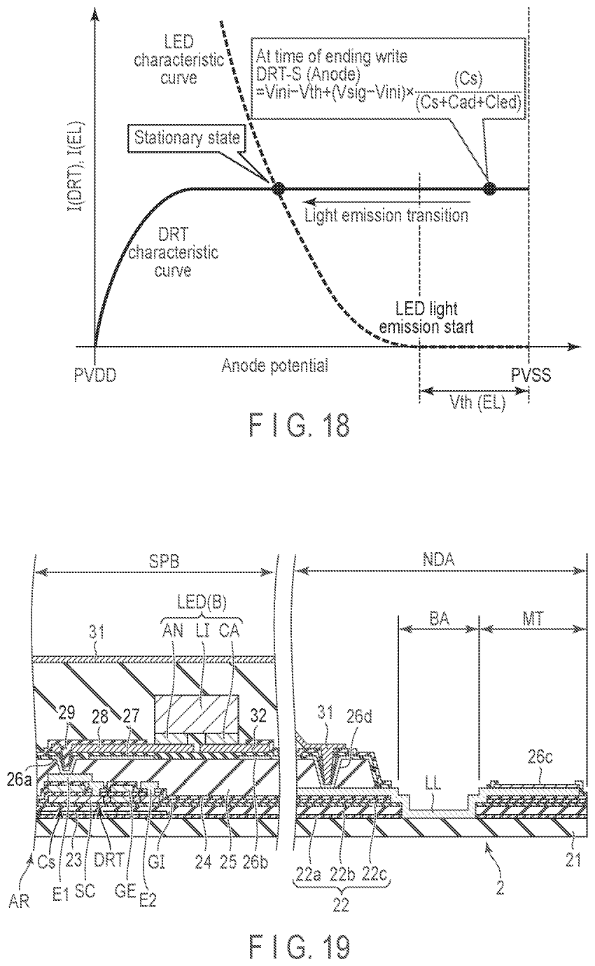

In this case, as illustrated in FIG. 18, after the potential of the source electrode of the drive transistor DRT represented by Formula (3) increases and a current starts to flow through the light emitting element LED, in the case in which Idrt=Iled, the potential increase of the source electrode of the drive transistor DRT stops, and a stationary state is obtained. Although not described in detail, since the current Iled (Idrt) is represented by Formula (1) above, a current that does not depend on Vth flows through the light emitting element LED.

The display device 1 (the display panel 2) according to the present embodiment can display various images by causing the light emitting element LED of each pixel PX (the sub-pixels SPR, SPG, and SPB) to emit light by each operation described above.

As described above, in the present embodiment, the conductive layer 26b formed between the pixel electrode 28 and the drive transistor DRT so as to overlap with the pixel electrode 28 at least partially in a planar view is provided, and the conductive layer 26b does not overlap with the region (mounting region of the light emitting element LED) of the pixel electrode 28 on which the light emitting element LED is mounted in a planar view.

In the present embodiment, with such a configuration, it is possible to suppress the occurrence of a defect such as a point defect due to a short circuit between the pixel electrode 28 (anode) and the conductive layer 26b (third metal) when the light emitting element LED (LED chip) is mounted, and thus it is possible to provide a highly reliable display device.

In the present embodiment, the conductive layer 26b is formed across the plurality of pixels PX (the sub-pixels SPR, SPG, and SPB), and has an opening formed at a position overlapping with the mounting region of the light emitting element LED in a planar view. According to such a configuration, as described above, a short circuit between the pixel electrode 28 and the conductive layer 26b can be avoided.

In the present embodiment, although it is described that the conductive layer 26b has the opening, the conductive layer 26b may be formed so as not to overlap with the mounting region of the light emitting element LED. That is, in the conductive layer 26b, for example, a slit (gap region) or the like may be formed instead of the opening.

In the present embodiment, the conductive layer 26b only has to be formed such that the end portion of the conductive layer 26b and the end portion of the mounting region of the light emitting element LED do not intersect in a planar view, and the shape or size of the opening or the slit described above is not limited.

In the present embodiment, the shape of the pixel electrode 28, the arrangement of the contact part electrically connecting the pixel electrode 28 and the drive transistor DRT, the arrangement of the mounting region of the light emitting element LED, and the like may be, for example, as illustrated in FIG. 7 or as illustrated in FIG. 9.

That is, in the present embodiment, even in the case in which the display device 1 is configured as illustrated in FIG. 7 or as illustrated in FIG. 9, it is possible to suppress the occurrence of defects by providing the openings 42R, 42G, and 42B.

In the present embodiment, the case is described in which the counter electrode 31 is disposed at the position facing the pixel electrode 28 through the light emitting element LED as illustrated in FIG. 6. However, the arrangement of the electrode connected to the positive electrode of the light emitting element LED and the electrode connected to the negative electrode of the light emitting element LED may be different from that in FIG. 6.

Specifically, as illustrated in FIG. 19, an electrode (in the following, referred to as a common electrode) 32 connected to the cathode CA of the light emitting element LED may be disposed on the same layer as the pixel electrode 28 connected to the anode AN of the light emitting element LED. In the case of such a configuration, the conductive layer 26b disposed between the layer in which the pixel electrode 28 and the common electrode 32 are disposed and the drive transistor DRT only has to be formed so as not to overlap with the mounting region of the light emitting element LED (the region of the pixel electrode 28 and the common electrode 32 on which the light emitting element LED is mounted) in a planar view. In FIG. 19, only the cross-sectional structure related to the sub-pixel SPB is illustrated for convenience, and the same applies to the other sub-pixels SPR and SPG.

The gap between the pixel electrode 28 and the common electrode 32 and the gap between the anode AN and the cathode CA of the light emitting element LED illustrated in FIG. 19 are planarized using, for example, a resin material along the upper surfaces of the anode AN and the cathode CA of the light emitting element LED.

The common electrode 32 only has to be continuously formed so as to be in contact with cathode CA of each light emitting element LED (IOT sputtering or the like).

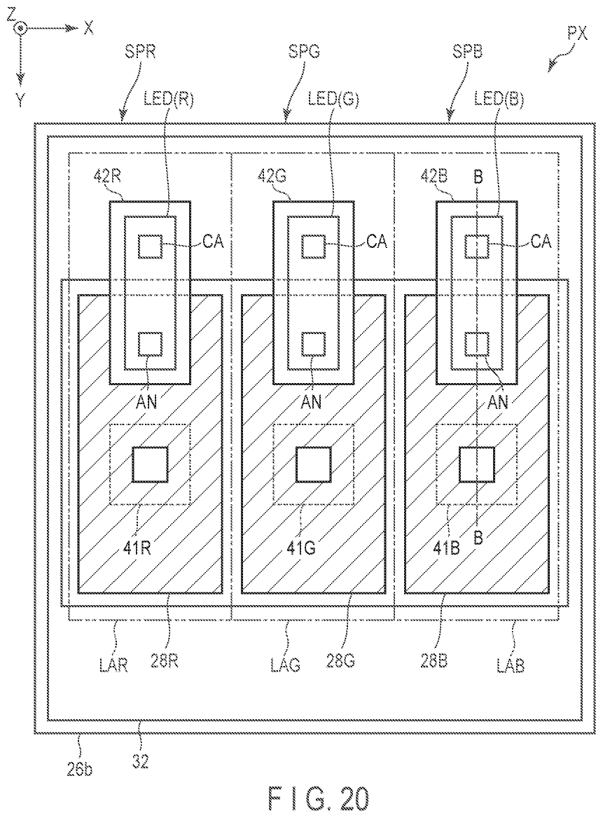

Here, FIG. 20 is a plan view illustrating an example of a layout (shape) of the conductive layer 26b to the pixel PX (the sub-pixels SPR, SPG, and SPB) in the case in which the pixel electrode 28 and the common electrode 32 are disposed in the same layer as illustrated in FIG. 19.

In FIG. 20, the same parts as those in FIG. 7 are denoted by the same reference numerals. Here, the detailed description of parts similar to those in FIG. 7 will be omitted, and parts different from those in FIG. 7 will be mainly described.

As illustrated in FIG. 20, the pixel PX including the sub-pixels SPR, SPG, and SPB shares the single conductive layer 26b and also shares the single common electrode 32.

As described above, the pixel electrode 28 and the common electrode 32 are disposed in the same layer. Therefore, in a planar view in FIG. 20, the pixel electrodes 28R, 28G, and 28B are each formed in a rectangular shape, and are disposed in openings formed in the common electrode 32.

As illustrated in FIG. 20, the light emitting element LED (R) is disposed across the pixel electrode 28R and the common electrode 32. Specifically, the light emitting element (R) is mounted such that the anode AN of the light emitting element LED (R) is connected to the pixel electrode 28R, and the cathode CA of the light emitting element LED (R) is connected to the common electrode 32. Here, the light emitting element LED (R) is described, and the same applies to the other light emitting elements LED (G) and LED (B).

Here, the conductive layer 26b has the openings 41R, 41G, and 41B. The opening 41R is an opening formed in the conductive layer 26b in order to contact the pixel electrode 28R to the drive transistor DRT included in the sub-pixel SPR. The opening 41G is an opening formed in the conductive layer 26b in order to contact the pixel electrode 28G to the drive transistor DRT included in the sub-pixel SPG. The opening 41B is an opening formed in the conductive layer 26b in order to contact the pixel electrode 28B to the drive transistor DRT included in the sub-pixel SPB. In the example illustrated in FIG. 20, the openings 41R, 41G, and 41B are disposed linearly extending in the first direction X.

The conductive layer 26b has openings 42R, 42G, and 42B. The opening 42R is an opening formed in the conductive layer 26b such that the conductive layer 26b does not overlap with the mounting region of the light emitting element LED (R) of the sub-pixel SPR. The opening 42G is an opening formed in the conductive layer 26b such that the conductive layer 26b does not overlap with the mounting region of the light emitting element LED (G) of the sub-pixel SPG. The opening 42B is an opening formed in the conductive layer 26b such that the conductive layer 26b does not overlap with the mounting region of the light emitting element LED (B) of the sub-pixel SPB. In the example illustrated in FIG. 20, the openings 42R, 42G, and 42B are disposed linearly extending in the first direction X.

In the example illustrated in FIG. 20, the opening 42R is formed slightly larger than the mounting region of the light emitting element LED (R) in a planar view. The opening 42R may be formed to have the same size as the opening (the opening for mounting the light emitting element LED (R)) provided in the insulating layer 29 described above.

The opening 42R only has to be formed larger than at least the mounting region of the light emitting element LED (R). The opening 42R only has to be formed so as not to overlap with the mounting region of the light emitting element LED (R) and such that the end portion of the mounting region and the end portion of the conductive layer 26b (opening 42R) do not cross each other. Here, the opening 42R is described, and the same applies to the openings 42G and 42B.

The portion corresponding to the sub-pixel SPB illustrated in FIG. 19 illustrates a cross-sectional structure (i.e., the cross-sectional structure including the openings 41B and 42B) taken along line B-B illustrated in FIG. 20.

Although FIG. 20 illustrates an example in which the openings 41R, 41G, and 41B and the openings 42R, 42G, and 42B are disposed linearly extending in the first direction X, the arrangement (i.e., the arrangement of the contact part between the pixel electrode 28 and the drive transistor DRT or the mounting region of the light emitting element LED) of the openings may be different from that illustrated in FIG. 20.

As described above, the present embodiment is applicable even in the case in which pixel electrode 28 and common electrode 32 are disposed in the same layer (i.e., in the case in which the electrodes of the micro LEDs have the same layer structure,), and thus the occurrence of the defect can be suppressed.

Although some embodiments of the present invention are described, these embodiments are presented as examples, and are not intended to limit the scope of the invention. These embodiments can be implemented in various other forms, and various omissions, replacements, and modifications can be made without departing from the gist of the invention. These embodiments and modifications are included in the scope and gist of the invention and are included in the invention described in the claims and the equivalent scope.

What is claimed is:

1. A display device comprising:
a substrate;
a pixel electrode disposed on the substrate;
a light emitting element mounted on the pixel electrode;
a drive transistor configured to control a current supplied to the light emitting element through the pixel electrode; and
a conductive layer formed between the pixel electrode and the drive transistor so as to at least partially overlap with the pixel electrode in a planar view, wherein
the conductive layer does not overlap with a region of the pixel electrode on which the light emitting element is mounted in a planar view.

2. The display device according to claim 1, further comprising a plurality of pixels each including the pixel electrode, wherein
the conductive layer is formed across the plurality of pixels, and the conductive layer has an opening formed at a position overlapping with a region of the pixel electrode on which the light emitting element is mounted in the planar view.

3. The display device according to claim 1, wherein
an end portion of the conductive layer does not overlap with an end portion of a region of the pixel electrode on which the light emitting element is mounted in a planar view.

4. The display device according to claim 1, further comprising a plurality of pixels each including the pixel electrode, the light emitting element, and the drive transistor, wherein
at least one of the pixel electrodes included in each of the plurality of pixels is formed in a non-rectangular shape in a planar view,
a contact part electrically connecting the pixel electrode included in each of the plurality of pixels to the drive transistor is disposed linearly extending in a first direction in a planar view, and
at least one of regions of the pixel electrode included in each of the plurality of pixels in which the light emitting element is mounted is not disposed linearly extending in a second direction in which a region of another pixel electrode in which the light emitting element is mounted is disposed in a planar view.

5. The display device according to claim 1, further comprising a plurality of pixels each including the pixel electrode, the light emitting element, and the drive transistor, wherein
the pixel electrode included in each of the plurality of pixels is formed in a rectangular shape in a planar view,
a contact part electrically connecting the pixel electrode included in each of the plurality of pixels to the drive transistor is disposed linearly extending in a first direction in a planar view, and
a region of the pixel electrode included in each of the plurality of pixels in which the light emitting element is mounted is disposed linearly extending in a second direction in a planar view.

6. The display device according to claim 1, further comprising a counter electrode, wherein
the counter electrode is positioned to face the pixel electrode, and
the light emitting element is sandwiched between the pixel electrode and the counter electrode.

7. A display device comprising:
a substrate;
a pixel electrode disposed on the substrate;
a common electrode disposed in an equal layer as the pixel electrode;
a light emitting element mounted on the pixel electrode and the common electrode;
a drive transistor configured to control a current supplied to the light emitting element through the pixel electrode; and
a conductive layer formed between the layer in which the pixel electrode and the common electrode are disposed and the drive transistor so as to at least partially overlap with the pixel electrode and the common electrode in a planar view, wherein
the conductive layer does not overlap with regions of the pixel electrode and the common electrode on which the light emitting element is mounted in a planar view.

8. The display device according to claim 7, further comprising a plurality of pixels each including the pixel electrode, wherein
the common electrode is formed across the plurality of pixels, and
a pixel electrode included in each of the plurality of pixels is disposed in an opening formed in the common electrode.

9. The display device according to claim 7, wherein
the conductive layer is formed across the plurality of pixels, and has an opening formed at a position not overlapping with a region of the pixel electrode and the common electrode on which the light emitting element is mounted in the planar view.

10. The display device according to claim 7, wherein
an end portion of the conductive layer does not overlap with an end portion of a region of the pixel electrode and the common electrode on which the light emitting element is mounted in a planar view.

11. The display device according to claim 7, further comprising a plurality of pixels each including the pixel electrode, the light emitting element, and the drive transistor, wherein
the pixel electrode included in each of the plurality of pixels is formed in a rectangular shape in a planar view,
a contact part electrically connecting the pixel electrode included in each of the plurality of pixels to the drive transistor is disposed linearly extending in a first direction in a planar view, and
a region of the pixel electrode and the common electrode included in each of the plurality of pixels in which the light emitting element is mounted is disposed linearly extending in a second direction in a planar view.
